(19) United States
(12) Patent Application Publication
(10) Pub. No.: US 2005/0178653 A1
(43) Pub. Date: Aug. 18, 2005

(54) Method for elimination of sputtering into the backing plate of a target/backing plate assembly

(76) Inventor: Charles Fisher, Pomona, NY (US)

Correspondence Address: PRAXAIR, INC.;LAW DEPARTMENT - M1 557, 39 OLD RIDGEBURY ROAD, DANBURY, CT, 06810-5113, US

(21) Appl. No.: 10/778,354

(22) Filed: Feb. 17, 2004

(51) Int. Cl. C23C 14/32

(52) U.S. Cl. 204/192.12; 204/298.12; 204/298.19

(57) ABSTRACT

A method for preventing sputtering into the backing plate of a sputter target assembly using a novel backing plate having an annular groove disposed on an area of an intended erosion groove of the sputter target and having a tubular channel connecting the groove to the atmosphere. A sputter target/backing plate assembly and an apparatus containing the novel backing plate are also disclosed.

### FIELD OF THE INVENTION

This invention relates to a method for elimination of sputtering into the backing plate of a sputter target/backing assembly in a sputtering apparatus using a novel backing plate with a groove disposed on an area compatible to and superimposed on the intended erosion groove of the sputter target.

### BACKGROUND OF THE INVENTION

Cathodic sputtering is widely used for the deposition of thin layers of material onto desired substrates. Basically, this process requires a gas ion bombardment of a target having a face formed of a desired material that is to be deposited as a thin film or layer on a substrate. Ion bombardment of the target not only causes atoms or molecules of the target materials to be sputtered, but imparts considerable thermal energy to the target. This heat is dissipated beneath or around a backing plate that is positioned in a heat exchange relationship with the target. The target forms a part of a cathode assembly that, together with an anode, is placed in a vacuum chamber filled with an inert gas, preferably argon. A high voltage electrical field is applied across the cathode and the anode. The inert gas is ionized by collision with electrons ejected from the cathode. Positively charged gas ions are attracted to the cathode and, upon impingement with the target surface, these ions dislodge the target material. The dislodged target material traverses the evacuated enclosure and deposits as a thin film on the desired substrate, which is normally located close to the anode.

In addition to the use of an electrical field, increasing sputtering rates have been achieved by the concurrent use of an arch-shaped magnetic field that is superimposed over the electrical field and formed in a closed loop configuration over the surface of the target. These methods are known as magnetron sputtering methods. The arch-shaped magnetic field traps electrons in an annular region adjacent to the target surface, thereby increasing the number of electron-gas atom collisions in the area to produce an increase in the number of positive gas ions in the regions that strike the target to dislodge the target material. Accordingly, the target material becomes eroded in a generally annular section of the target face, known as the erosion groove.

In a conventional target cathode assembly, the target is attached at a single bonding surface to a nonmagnetic backing plate to form a parallel interface in the assembly. The backing plate is used to provide a means for holding the target assembly in the sputtering chamber and to provide structural stability to the target assembly. Also, the backing plate is normally water-cooled to carry away the heat generated by the ion bombardment of the target. Magnets are typically arranged beneath the backing plate in well-defined positions to form the above-noted magnetic field in the form of a loop or tunnel extending around the exposed face of the target.

However, a localized erosion groove is generally generated in the sputter target. The rotation of a magnet assembly can cause the erosion over a wider area of the target. There is a risk that the entire thickness of the target can be exhausted at the bottom of the groove and thus contaminate the substrate, e.g., wafer, with the material of the backing plate. It has been suggested that wax is placed in a groove but the sputtering of the wax would contaminate the substrate. To prevent this target blow out, it was suggested that it would be better to only use about forty percent of the sputter target in order to avoid the contamination problem.

It is an object of the present invention to provide a method for eliminating the sputtering onto the backing plate of a sputter target/backing plate assembly using a novel backing plate design.

It is another object of the present invention to provide a sputtering apparatus with a novel backing plate that will eliminate sputtering into the backing plate when operating.

It is another object of the present invention to provide a novel design for a backing plate for a sputter target/backing plate assembly.

### SUMMARY OF THE INVENTION

One embodiment of the present invention provides a method for preventing the sputtering into the backing plate of a sputter target/backing plate assembly in a sputtering apparatus comprising the steps:
a) mounting a sputter target/backing plate assembly having said backing plate with at least one groove disposed in an area that is compatible to and superimposed on the intended erosion groove of said sputter target and having at least one hollow tubular channel in the backing plate connecting the groove to the atmosphere; a chamber for containing said sputter target/backing plate and a substrate; and a magnetic means which in combination forms a magnetic sputtering apparatus;
b) inerting the chamber containing sputter target/backing plate assembly and substrate such as a wafer;
c) energizing the sputter target/backing plate assembly and magnetic source means to create lines of magnetic flow to sweep the sputter target surface and therefore depleting the sputter target material and depositing said material on the substrate while at the same time the lines of magnetic flow form an erosion groove on the surface of the sputtering target; and
d) continuing the coating of the substrate in step c) until an opening appears in the erosion groove exposing the groove in the backing plate to the atmosphere via the tubular channel.

When an opening or hole is formed in the erosion groove of the sputter target, the tubular channel connecting the backing plate groove to the atmosphere will allow air to enter the chamber and cause the sputtering apparatus to fault out or shut down. Thus upon the initial opening in the erosion groove, the sputtering apparatus will shut down, permitting maximum use of the sputter target material. Various sensing means can be employed to sense the opening in the erosion groove such as a cryo pump that will heat up and close a gate valve as soon as atmosphere enters the chamber. Upon shut down, the chamber can vent slowly while a new sputter target is installed and then the process can quickly be restored.

Preferably the groove would be an annular shape with a radial width between about 1 and about 2 inches, most preferably between about 1 and about 1½ inches; and a depth of the groove could be between about ⅛ and about 3/4 inch, preferably between about ¼ and about 1/2 inch; and more preferably between about ⅜ and about 1/2 inch. Preferably the area of the opening in the tubular channel is about 0.00019 and about 0.0123 square inch and more preferably between about 0.00019 and about 0.00077 square inch.

Another embodiment of the invention is a sputter target/backing plate assembly having a novel backing plate with at least one groove disposed in an area on its bonding surface that is compatible to and superimposed on the intended erosion groove of the sputter target and at least one tubular channel connecting the groove to the atmosphere.

Another embodiment of the invention is a magnetron apparatus comprising:
a) an inert gas chamber including means for positioning a substrate having a surface to be coated and a means for positioning a sputter target/backing plate assembly in which the backing plate has at least one groove in its bonding surface and at least one hollow tubular channel connecting the groove to the atmosphere and target having a source of coating material;
b) a magnetic source means to be positioned behind the target and comprising a permanent magnet radially oriented within a magnetically permeable ring which is connected to a drive shaft and means adapted for flowing of coolant to cause movement of the magnetic source means with respect to the source of coating material such that lines of magnetic flux created will sweep the target surface of the source of coating material; and
c) power means for energizing the magnetic source means and sputter target/backing plate assembly so that the coating material may be transferred from the sputter target to the surface to be coated and the motion of the magnetic source can deplete the source of coating material and coat the surface of the substrate.

As used herein, groove could be a complete annular groove, any segment of an annular groove or any shaped groove.

To achieve good thermal and electrical contact between the sputter target and the backing plate, these members are commonly attached to each other by use of soldering, brazing, diffusion bonding, mechanical fastening or epoxy bonding.

The metals used for the sputter target and backing plate may be any of a number of different metals, either in pure or alloy form. For example, the sputter target may be made of titanium, aluminum, copper, molybdenum, cobalt, chromium, ruthenium, rhodium, palladium, silver, osmium, iridium, platinum, gold, tungsten, silicon, tantalum, vanadium, nickel, iron, manganese, germanium, or an alloy thereof. The backing plate could be made of copper, aluminum, titanium, or alloys thereof. Preferred sputter target/backing plate metal pairings include a titanium target bonded to an aluminum backing plate; a titanium target bonded to an copper backing plate; a titanium target bonded to a titanium backing plate; a molybdenum target bonded to a copper backing plate; a cobalt target bonded to a copper backing plate; a chromium target bonded to copper backing plate; and a target formed of a precious metal such as ruthenium, rhodium, palladium, silver, osmium, iridium, platinum or gold, bonded to a copper backing plate. If a titanium-tungsten alloy is used, the alloy preferably includes about 10% to 15% titanium by weight.

Although the drawings have been described in conjunction with a disc-shaped sputter target/backing plate assembly, it will be readily apparent to one of ordinary skill that the method may be used to bond sputter targets and backing plates having any of a number of different shapes and sizes.

### BRIEF DESCRIPTION OF THE DRAWINGS

FIG. 1 shows a partial cross-sectioned view of a prior art sputtering apparatus as disclosed in U.S. Pat. No. 5,252,194.

FIG. 2 shows the erosion profile of the target from FIG. 1.

FIG. 3 shows the erosion profile of a typical stationary magnetic assembly.

FIG. 4 shows a partial perspective view of a disc-shaped backing plate of the invention.

FIG. 5 shows a side elevation view of the backing plate of FIG. 4.

### DETAILED DESCRIPTION OF THE INVENTION

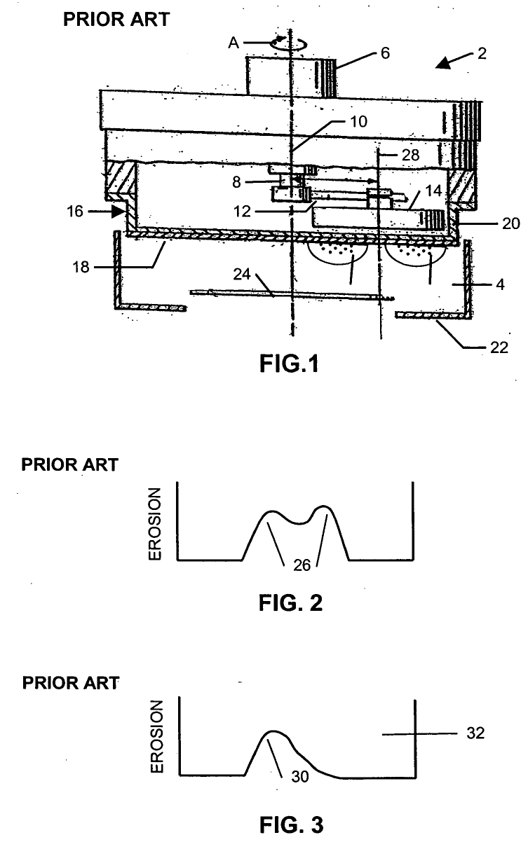

FIG. 1 shows a prior art sputtering apparatus 2 comprising a vacuum chamber 4; a motor 6 adapted for rotating a shaft 8 about axis 10 (arrow A); a magnet support shaft 12 supporting magnet assembly 14; and sputter target/backing plate assembly 16 containing sputter target 18 and backing plate 20. The target (cathode) 18 is connected to a negative voltage (not shown). Plasma shield 22 is electrically grounded and serves as an anode. Wafer 24 is supported in the chamber 4. In operation motor 6 rotates shaft 8 so that the entire magnet assembly 14 is rotated about axis 10. The erosion pattern produced in target 18 by this rotation is an annular groove 26 as shown in FIG. 2. Discharge 26 is shown in its initial position and rotates with axis 28 about axis 10. As stated above, this produces a non-uniform annular groove 26 as shown in FIG. 2.

FIG. 3 is the erosion profile 30 in a target 32 of a stationary magnetic assembly.

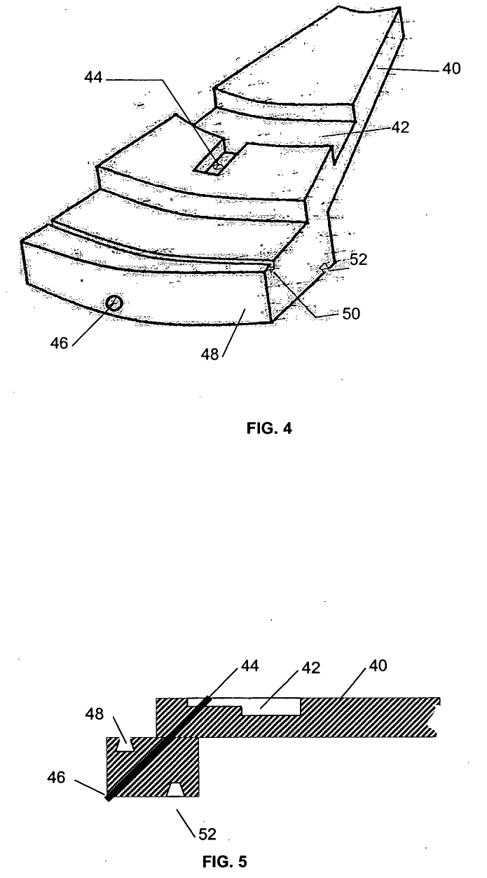

In FIGS. 4 and 5, a partial perspective view is shown of a disc-shaped backing plate 40 having an annular air groove 42 containing a tubular channel 44 having an exit opening 46 in the peripheral wall 48. A common vacuum seal groove 50 and water seal groove 52 is shown in the backing plate 40. The annular groove 42 is positioned in the intended erosion groove (26 or 30) of a sputter target of the type shown in FIGS. 2 and 3. Thus when an opening occurs in the sputter target, the tubular channel will cause air from the atmosphere to enter the groove 42 and then into the chamber of the sputtering apparatus causing the sputtering to fault out.

While the present invention has been illustrated by the description of an embodiment thereof, and while the embodiment has been described in considerable detail, it is not intended to restrict or in any way limit the scope of the appended claims to such detail. Additional advantages and modifications will readily appear to those skilled in the art. The invention in its broader aspects is therefore not limited to the specific details, representative assembly and method shown and described. Accordingly, departures may be made from such details without departing from the scope or spirit of applicant's general inventive concept.

1. A method for preventing the sputtering onto the backing plate of a sputter target/backing plate assembly in a sputtering apparatus comprising the steps:
a) mounting a sputter target/backing plate assembly having said backing plate with at least one groove disposed in an area that is compatible to and superimposed on the intended erosion groove of said sputter target and having at least one hollow tubular channel in the backing plate connecting the groove to the atmosphere; a chamber for containing said sputter target/backing plate and a substrate; and a magnetic means which in combination forms a magnetic sputtering apparatus;
b) inerting the chamber containing sputter target/backing plate assembly and substrate;
c) energizing the sputter target/backing plate assembly and magnetic source means to create lines of magnetic flow to sweep the sputter target surface and therefore depleting the sputter target material and depositing said material on the substrate while at the same time the lines of magnetic flow form an erosion groove on the surface of the sputtering target; and
d) continuing the coating of the substrate in step c) until an opening appears in the erosion groove exposing the groove in the backing plate to the atmosphere via the tubular channel.

2. The method of claim 1 wherein said backing plate is disc shaped and said groove is an annular groove.

3. The method of claim 2 wherein the radial width of the annular groove is between about 1 and about 2 inches.

4. The method of claim 3 wherein the depth of the annular groove is between about ⅛ and about 3/4 inch.

5. The method of claim 4 wherein the area of the opening in the tubular channel is between about 0.00019 and about 0.0123 square inch.

6. The method of claim 1 wherein the backing plate is made of a material selected from the group comprising copper, aluminum, titanium, and alloys thereof.

7. The method of claim 1 wherein the sputter target is made of a material selected from the group comprising titanium, aluminum, copper, molybdenum, cobalt, chromium, ruthenium, rhodium, palladium, silver, osmium, iridium, platinum, gold, tungsten, silicon, tantalum, vanadium, nickel, iron, manganese, germanium, or alloys thereof.

8. A sputter target assembly comprising a backing plate with at least one groove disposed in an area on its bonding surface that is compatible to and superimposed on with the intended erosion groove of the sputter target and at least one hollow tubular channel connecting the groove to the atmosphere.

9. The sputter target backing plate assembly of claim 8 wherein said backing plate is disc shaped and said groove is an annular groove.

10. The sputter target backing plate assembly of claim 9 wherein the radial width of the annular groove is between about 1 and about 2 inches.

11. The sputter target backing plate assembly of claim 10 wherein the depth of the annular groove is between about ⅛ and about 3/4 inch.

12. The sputter target backing plate assembly of claim 11 wherein the area of the opening in the tubular channel is between about 0.00019 and about 0.0123 square inch.

13. The sputter target backing plate assembly of claim 8 wherein the backing plate is made of a material selected from the group comprising copper, aluminum, titanium, and alloys thereof.

14. The sputter target backing plate assembly of claim 8 wherein the sputter target is made of a material selected from the group comprising titanium, aluminum, copper, molybdenum, cobalt, chromium, ruthenium, rhodium, palladium, silver, osmium, iridium, platinum, gold, tungsten, silicon, tantalum, vanadium, nickel, iron, manganese, germanium, or alloys thereof.

15. A magnetron apparatus comprising:
a) an inert gas chamber including means for positioning an substrate having a surface to be coated and a means for positioning a sputter target/backing plate assembly in which the backing plate has at least one groove in its bonding surface and at least one hollow tubular channel connecting the groove to the atmosphere and said target having a source of coating material;
b) a magnetic source means to be positioned behind the target and comprising a permanent magnet radially oriented within a magnetically permeable ring which is connected to a drive shaft and means adapted for flowing of coolant to cause movement of the magnetic source means with respect to the source of coating material such that lines of magnetic flux created will sweep the target surface of the source of coating material; and
c) power means for energizing the magnetic source means and sputter target/backing plate assembly so that the coating material may be transferred from the sputter target to the surface to be coated and the motion of the magnetic source can deplete the source of coating material and coat the surface of the substrate.

16. The magnetron apparatus of claim 15 wherein said backing plate is disc shaped and said groove is an annular groove.

17. The magnetron apparatus of claim 16 wherein the radial width of the annular groove is between about 1 and about 2 inch.

18. The magnetron apparatus of claim 17 wherein the depth of the annular groove is between about ⅛ and about 3/4 inch.

19. The magnetron apparatus of claim 18 wherein the area of the opening of the tubular channel is between about 0.00019 and about 0.0123 square inch.

20. The magnetron apparatus of claim 15 wherein the backing plate is made of a material selected from the group comprising copper, aluminum, titanium, and alloys thereof; and the sputter target is made of a material selected from the group comprising titanium, aluminum, copper, molybdenum, cobalt, chromium, ruthenium, rhodium, palladium, silver, osmium, iridium, platinum, gold, tungsten, silicon, tantalum, vanadium, nickel, iron, manganese, germanium, or alloys thereof.
